(19) United States
(12) Patent Application Publication
(10) Pub. No.: US 2004/0212439 A1
(43) Pub. Date: Oct. 28, 2004

(54) Voltage controlled oscillator

(76) Inventor: Simon Peter Goddard, Sheffield (GB)

Correspondence Address: EPSTEIN DRANGEL BAZERMAN & JAMES, LLP, 60 EAST 42ND STREET, SUITE 820, NEW YORK, NY, 10165, US

(21) Appl. No.: 10/422,560

(22) Filed: Apr. 24, 2003

(51) Int. Cl. H03L 7/00

(52) U.S. Cl. 331/16

(57) ABSTRACT

Embodiments of the present invention relate to a voltage controlled oscillator having a substantially constant modulation index. The oscillator uses a plurality of MOS varactors to, firstly, select the centre frequency of oscillation of the modulator and, secondly, to control the degree of modulation of that frequency.

### FIELD OF THE INVENTION

The present invention relates to the voltage controlled oscillator and, more particularly, to a voltage controlled oscillator having a relatively stable modulation index.

### BACKGROUND TO THE INVENTION

Radio transmitters that use frequency modulation or a form of frequency shift keying may, for the purposes of costs and power consumption, implement direct modulation of a signal produced by a voltage controlled oscillator. It is well known within the art that the change in frequency per unit change in voltage applied to a voltage controlled oscillator is not constant across a tuning range of interest for a voltage-controlled oscillator. Such a variation in the modulation index is, at best, undesirable in most radio systems. Suitably, many voltage controlled oscillators such as, for example, those using varactor diodes, require time consuming calibration as well as being expensive and requiring memory to accommodate any such changes in modulation index. Furthermore, varactor diode based voltage controlled oscillators produce uneven or unbalanced positive and negative frequency deviations and are not suited to very low voltage applications that use, for example, voltages of one volt or less.

It is an object of embodiments of the present invention at least to mitigate some of the problems of the prior art.

### SUMMARY OF INVENTION

Accordingly, a first aspect of embodiments of the present invention provides a voltage controlled oscillator comprising means, responsive to a first signal (V_{TUNE}), for producing an output signal having a frequency (106,108,104,114); means (124;128) for producing a variable modulation signal (V_{MOD}) and means (110,112), responsive to the variable modulation signal (V_{MOD}), for modulating the frequency of the output signal; the variable modulation signal (V_{MOD}) being derived from the first signal (V_{TUNE}) and a data signal (V_{DATA}) and arranged to bias the means (110,112) for modulating the frequency of the output signal to produce a substantially constant modulation index over a predeterminable frequency range.

Advantageously, embodiments of the present invention enable a voltage controlled oscillator to be realised that has a relatively stable or substantially constant modulation index.

A further aspect of embodiments of the present invention provides a modulator comprising a voltage controlled oscillator as described herein. Preferably, the modulator is an FM or FSK modulator.

### BRIEF DESCRIPTION IF THE DRAWINGS

Embodiments of the present invention will now be described, by way of example only, with reference to the accompanying drawings in which:

FIG. 1 shows a voltage controlled oscillator according to a first embodiment; and

FIG. 2 shows a graph of a variation of the gain of the voltage controlled oscillator with a modulation voltage.

### DETAILED DESCRIPTION OF THE PREFERRED EMBODIMENTS

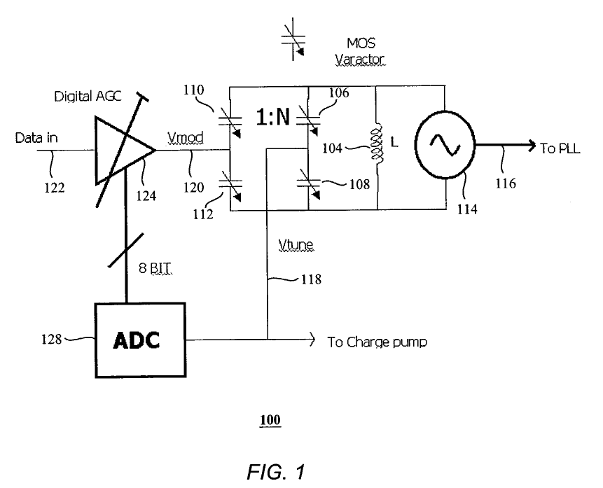

FIG. 1 shows a voltage controlled oscillator 100 according to a first embodiment. The voltage controlled oscillator 100 comprises a tuneable LC circuit 102 comprising an inductor 104 in parallel with, firstly, a pair of series arranged tuning MOS varactors 106 and 108 and, secondly, a pair of series arranged modulation MOS varactors 110 and 112. The circuit 100 also comprises a CMOS oscillator 114 having an output signal frequency that is influenced by the LC circuit 102. The frequency of the output signal 116 of the oscillator 114 is controlled, in broad terms, by a tuning voltage Vₜᵤₙₑ 118. The tuning voltage 118 is applied to the node between the series arrangement of the tuning MOS varactors 106 and 108.

A modulation voltage, V_{mod}, 120 is applied to the mid-point of the modulation varactors 110 and 112 to influence the frequency of the output signal 116 in response to data of a data signal 122. The magnitude of the modulation voltage 120 is controlled using a digital automatic gain control amplifier 124. The gain of the amplifier is controlled by the digital output signal 126 produced by an analogue-to-digital converter 128. The analogue-to-digital converter is arranged to produce the digital output signal 126 in response to digitising the tuning voltage 118.

The frequency deviation of the output signal 116 in response to the data signal 122 is given by

F_{DEV}=K_{VCO}·V_{MOD},

where K_{VCO} is the voltage controlled oscillator gain and V_{MOD} is the magnitude of the modulation voltage.

In a preferred embodiment, the ratio of the net capacitance of the modulation varactors 110 and 112 to the net capacitance of the tuning MOS varactors 106 and 108 is 1:N. It will be appreciated by one skilled in the art that the ratio of the capacitances can be varied according to a desired or target application. Example applications are cordless phones and Bluetooth operating in the 2.4 GHz ISM band. The cordless phones use FSK with a 500 kHz deviation. For a number of reasons the VCOs for such phones are often run at twice the frequency ie 4.8 GHz. If it is assumed that an oscillator has a typical, nominal, gain of K_{VCO}=500 MHz/V with respect to V_{TUNE} and 5 MHz/V with respect to V_{MOD} and V_{DATA} of +/−0.1V, then N is approximately 90 to 70. If no other capacitors are present, in the example, then N might be 100. However, in practice, N would typically need to be adjusted downwards to compensate for oscillator parasitic capacitance. In practice, a precise value for N would be found by simulation. Bluetooth uses about a 150 kHz deviation. Therefore, given the same assumptions above, N would take values in the range of about 300 to 233. Furthermore, the magnitudes of the controlling voltages can also be selected according to a desired variation in capacitance.

One skilled in the art appreciates that a 2:1 capacitance variation for a 1V change in V_{TUNE} can be achieved using MOS varactors. Such a relatively large capacitance variation with respect to V_{TUNE} is desirable to compensate for at least one of tolerances on L and C and also to allow different frequencies channels to be realised, that is, to achieve a desired numbers of channels having an appropriate channel spacing. It will be appreciated that such a 2:1 change in capacitance for a relatively small controlling voltage compares favourably with the 2:1 change is capacitance exhibited by diode varactors for a relatively large, 2V, controlling voltage.

As is conventional, the values of capacitance for the modulator MOS varactors and the tuning MOS varactors depend upon the desired frequency of operation according to

$$f = \frac{1}{2 π \sqrt{LC}} .$$

Therefore, a 4 GHz VCO, might have an inductance of 1.27 nH and a total capacitance of 1.24 pF. The MOS devices can be dimensioned accordingly.

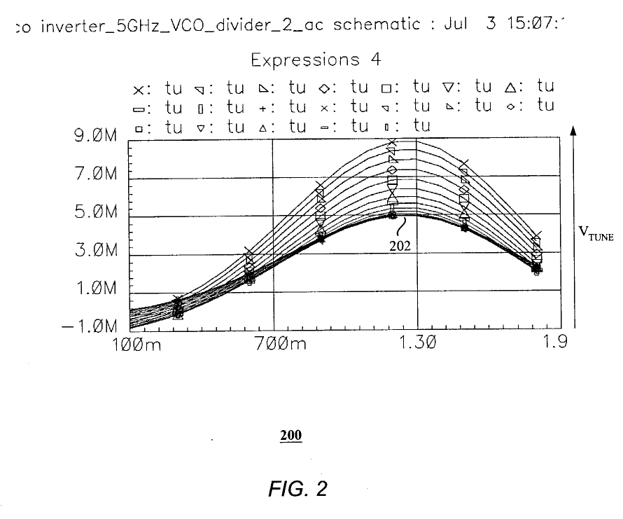

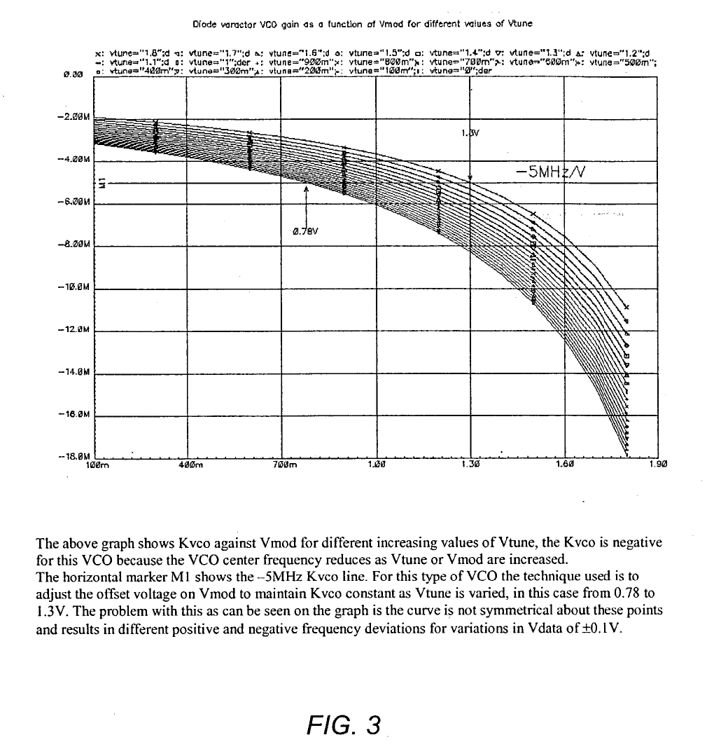

Referring to FIG. 2, there is shown a graph 200 of the variation of the gain, K_{VCO}, of the voltage controlled oscillator 100 with the modulating voltage, V_{MOD}. The illustrated graph 200 applies to an embodiment of the voltage controlled oscillator in which a ±500 kHz deviation is required. The modulation voltage carries a bias or offset that is arranged to ensure that the circuit is operable in a region 202 of substantially constant gain. Therefore, in an embodiment, the modulating voltage, V_{MOD}, is be set to be just less than 1.3 volts. Therefore, at relatively low values of the tuning voltages, V_{TUNE}, values of 1.3 V±0.1 V for the modulation voltage, V_{MOD}, should give an approximate ±500 KHz deviation. As V_{TUNE} increases, K_{VCO} increases. Therefore, V_{MOD} should be reduced in portion. In a particular embodiment specific embodiment described above, a preferred reduction factor was found to be 5/9. The scaling factor of 5/9 has been, for some embodiments, derived from the maximum and minimum deviation that would, but for the invention, occur in response to respective values of V_{DATA}. For example, VCOs having been found to exhibit a K_{VCO}=9 MHz/V for relatively high values of V_{TUNE} and a K_{VCO}=5 MHz/v for relatively low values of V_{TUNE}. Accordingly, the values of reduction factor can be selected according the frequency variations that need to be addressed or compensated for. It will be appreciated that to keep F_{dev}=K_{VCO}·V_{MOD} substantially constant, one should reduce VMOD in the same proportion that K_{VCO} is increased. This is achieved by varying the again of the AGC amplifier. The simulation that resulted in FIG. 2 used a value of N of 80 for a frequency deviation of 500 kHz.

Furthermore, if the offset voltage is chosen correctly, that is, the offset is arranged such that the circuit 100 operates in a region of the characteristic that is substantially symmetrical, the frequency deviation is substantially the same for positive and negative voltage variations in modulating voltage 120. It can be appreciated that the substantially constant region 202 of gain is present for various values of tuning voltage.

In preferred embodiments, the digital AGC amplifier 124 is arranged to have gain values that are governed, predominately, by resistor matching.

The embodiment resulting in the graphs shown in FIG. 2 used a 1.8V supply voltage, which allows the illustrated bias voltage of 1.3V. If a 1V supply was being used then the bias voltage might be adjusted, by redesigning the VCO, to be 0.5V, if required.

Referring to FIG. 3, there is shown a graph 300 of the variation of K_{VCO} with V_{MOD} for a diode varactor based VCO for different values of V_{TUNE} according to the prior art. The horizontal marker, M1, shows a −5 MHz K_{VCO} line. For the VCO simulated, embodiments of the present invention might be used to adjust the offset voltage on V_{MOD} to maintain K_{VCO} substantially constant as V_{TUNE} is varied, in the present case, from 0.78V to 1.3V. However, it can be appreciated that a significant problem associated with the graph 300 is that there is a lack of symmetry about such operating voltages, which will result in different positive and negative frequency deviations for substantially symmetrical variations in V_{DATA} of, for example, +/−0.1V.

It will be appreciated that the voltage controlled oscillator according to embodiments of the present invention can be used to realise modulators. Preferred embodiments of such modulators perform frequency modulation and, in particular, frequency shift keying.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

1. A voltage controlled oscillator comprising means, responsive to a first signal (V_{TUNE}), for producing an output signal having a frequency (106,108,104,114); means (124;128) for producing a variable modulation signal (V_{MOD}) and means (110,112), responsive to the variable modulation signal (V_{MOD}), for modulating the frequency of the output signal; the variable modulation signal (V_{MOD}) being derived from the first signal (V_{TUNE}) and a data signal (V_{DATA}) and arranged to bias the means (110,112) for modulating the frequency of the output signal to produce a substantially constant modulation index over a predeterminable frequency range.

2. A voltage controlled oscillator as claimed in claim 1 in which the means for producing the variable signal is responsive to a characteristic of the first signal.

3. A voltage controlled oscillator as claimed in claim 2 in which the characteristic of the first signal is the magnitude of the first signal.

4. A voltage controlled oscillator as claimed in claims 1, 2 or 3 in which the means for producing a variable modulation signal comprises means to bias the means for modulating the frequency of the output signal at a predetermined bias level.

5. A voltage controlled oscillator as claimed in claim 4 in which the predetermined bias level is selected to produce the substantially constant modulation index over the predetermined frequency range.

6. A voltage controlled oscillator as claimed in claims 1, 2, or 3 in which the means for producing the variable modulation signal comprises a variable gain amplifier (124), responsive to the first signal (V_{TUNE}) to vary the amplitude of the modulation signal (V_{MOD}).

7. A voltage controlled oscillator as claimed in claim 4 in which the means for producing the variable modulation signal comprises a variable gain amplifier (124), responsive to the first signal (V_{TUNE}) to vary the amplitude of the modulation signal (V_{MOD}).

8. A voltage controlled oscillator as claimed in claim 5 in which the means for producing the variable modulation signal comprises a variable gain amplifier (124), responsive to the first signal (V_{TUNE}) to vary the amplitude of the modulation signal (V_{MOD}).

9. A voltage controlled oscillator as claimed in claims 1, 2, or 3 in which the means for modulating the frequency of the output signal comprises at least a first pair of MOS devices (110;112).

10. A voltage controlled oscillator as claimed in claim 9 in which the first pair of MOS devices are MOS varactors (110;112).

11. A voltage controlled oscillator as claimed in claims 1, 2 or 3 in which the means for producing an output signal having a frequency comprises a respective pair of MOS devices (106;108).

12. A voltage controlled oscillator as claimed in claim 11 in which the respective pair of MOS devices comprises a pair of MOS varactors (106;108).

13. A voltage controlled oscillator as claimed in claim 11 in which the ratio of the capacitances of the MOS varactors (106;108) of the respective pair to the capacitances of the MOS varactors (110;112) of the first pair is N:1.

14. A method of controlling the frequency of an output signal produced by a voltage controlled oscillator; the method comprising the steps of deriving an offset signal (V_{OFFSET}) from a frequency tuning signal (V_{TUNE}), producing a modulating signal (V_{MOD}) using the offset signal (V_{OFFSET}) and a data signal (V_{DATA}) and producing the output signal using the modulating signal.
